(19) United States
(12) Patent Application Publication
(10) Pub. No.: US 2012/0208327 A1
(43) Pub. Date: Aug. 16, 2012

(54) IMPRINT APPARATUS AND MANUFACTURING METHOD OF SEMICONDUCTOR SUBSTRATE

(76) Inventor: Yasuo MATSUOKA, Kanagawa (JP)

(21) Appl. No.: 13/364,658

(22) Filed: Feb. 2, 2012

(30) Foreign Application Priority Data
Feb. 15, 2011 (JP) 2011-029643

(51) Int. Cl. H01L 21/50; B05C 11/00; B05C 9/12

(52) U.S. Cl. 438/127; 118/679; 257/E21.499

(57) ABSTRACT

According to one embodiment, an imprint apparatus includes an ejection unit, an ejection command generating unit, a determining unit, a prohibition command generating unit, and an ejection control unit. The ejection unit ejects a resin material. The ejection command generating unit generates an ejection command based on a drop recipe. The determining unit determines the presence or absence of a processing target substrate in an ejection destination of the resin material. The prohibition command generating unit, when the processing target substrate is not present in an ejection destination, generates an ejection prohibition command. The ejection control unit gives priority to the ejection prohibition command over the ejection command.

### CROSS-REFERENCE TO RELATED APPLICATIONS

This application is based upon and claims the benefit of priority from Japanese Patent Application No. 2011-029643, filed on Feb. 15, 2011; the entire contents of all of) which are incorporated herein by reference.

### FIELD

Embodiments described herein relate generally to an imprint apparatus and a manufacturing method of a semiconductor substrate.

### BACKGROUND

The nanoimprint lithography technology (hereinafter, simply, nanoimprinting) is known as a manufacturing technology of semiconductor integrated circuits. The nanoimprinting is a technology of transferring a pattern formed on a template onto a resist by pressing the template on which the pattern of a semiconductor integrated circuit is formed against the resist applied to a semiconductor wafer. Control of an amount of a resist material applied is performed based on a drop recipe defining an application amount distribution of a resist material to a semiconductor wafer.

In such application of a resist material, it is desired to apply a resist material while suppressing protrusion thereof from a wafer. Moreover, an application area of a resist material is desired to be as close as possible to the end portion of a wafer.

### BRIEF DESCRIPTION OF THE DRAWINGS

FIG. 1A is a diagram explaining a transferring process by nanoimprinting;

FIG. 1B is a diagram explaining the transferring process by nanoimprinting;

FIG. 1C is a diagram explaining the transferring process by nanoimprinting;

FIG. 2 is a block diagram illustrating a schematic configuration of an imprint apparatus in a first embodiment;

FIG. 3 is a diagram illustrating a schematic configuration of an ejection unit viewed from an ejection port side;

FIG. 4 is a partially enlarged cross-sectional view illustrating a detailed configuration of the ejection unit;

FIG. 5 is a plan view of a wafer for explaining a shot arrangement;

FIG. 6 is a diagram illustrating an application example of a resist material by a drop recipe;

FIG. 7 is a block diagram illustrating a schematic configuration of an imprint control unit;

FIG. 8A is a diagram illustrating an application example of a resist material at an end portion of a wafer;

FIG. 8B is a timing chart for explaining each command when applying a resist material to the end portion of the wafer shown in FIG. 8A;

FIG. 9 is a flowchart for explaining a nanoimprinting process by the imprint apparatus;

FIG. 10 is a block diagram illustrating a schematic configuration of an imprint control unit included in an imprint apparatus in a second embodiment; and

FIG. 11 is a diagram illustrating an example of a prohibited area partition information for one shot.

### DETAILED DESCRIPTION

In general, according to one embodiment, an imprint apparatus is an imprint apparatus that applies a curable resin material to a processing target substrate and transfers a pattern of a semiconductor integrated circuit formed on a template onto the curable resin material applied to the processing target substrate. The imprint apparatus includes an ejection unit, a recipe storing unit, an ejection command generating unit, a determining unit, a prohibition command generating unit, and an ejection control unit. The ejection unit is configured by aligning a plurality of ejection ports and ejects the curable resin material toward the processing target substrate. The recipe storing unit stores therein a drop recipe indicating an application amount distribution of the curable resin material to the processing target substrate. The ejection command generating unit generates an ejection command of the curable resin material to the ejection unit based on the drop recipe. The determining unit is a CCD line sensor arranged parallel to an alignment direction of the ejection ports and determines whether the processing target substrate is present in an ejection destination of the curable resin material from the ejection unit. The prohibition command generating unit, when the determining unit determines that the processing target substrate is not present, generates an ejection prohibition command of the curable resin material to the ejection unit. The ejection control unit causes the ejection unit to eject the curable resin material by giving priority to the ejection prohibition command over the ejection command. The detection positions by the CCD line sensor and positions to be an ejection destination of the curable resin material by the ejection ports are approximately in one-to-one correspondence with each other.

Exemplary embodiments of an imprint apparatus and a manufacturing method of a semiconductor substrate according to the embodiments will be explained below in detail with reference to the accompanying drawings. The present invention is not limited to the following embodiments.

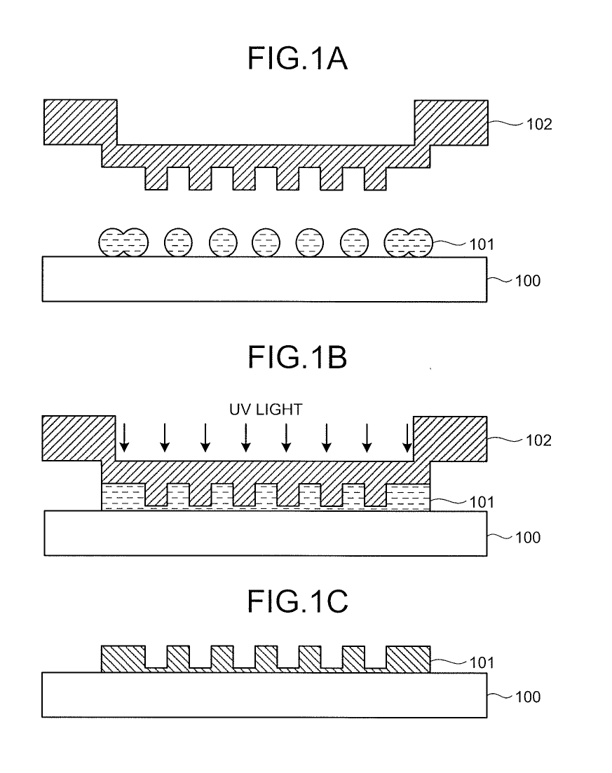

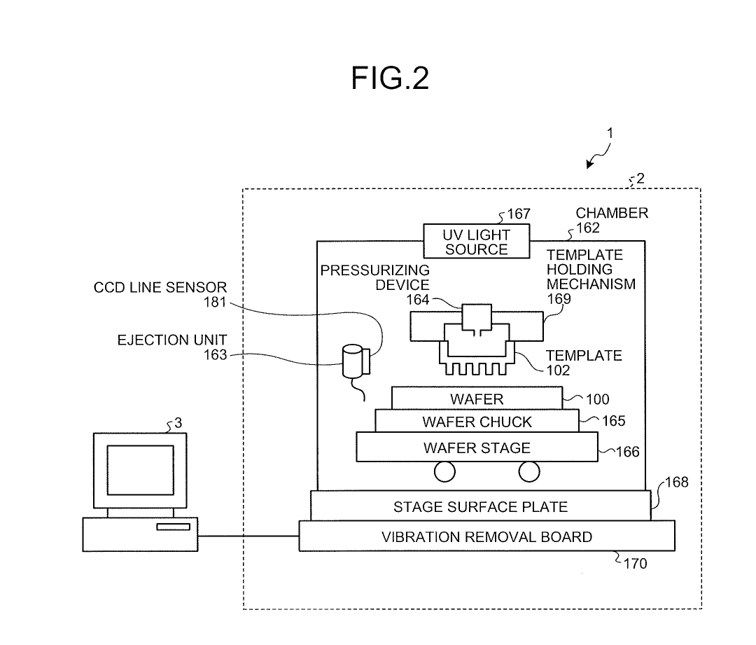

First, a typical transferring process by nanoimprinting is explained. FIG. 1A to FIG. 1C are diagrams explaining the transferring process by nanoimprinting. FIG. 2 is a block diagram illustrating a schematic configuration of an imprint apparatus. In this embodiment, as an example, photo-nanoimprint of causing resist (photocurable resin material) to cure by ultraviolet irradiation is explained. In addition, the present embodiment can be applied also to thermal nanoimprinting of causing resist (thermosetting resin material) to cure by heating.

In the transferring process, first, as shown in FIG. 1A, a resist material 101 (an example of a curable resin material) is applied to a wafer 100 (an example of a processing target substrate) as a process target. An imprint apparatus 1 includes an ejection unit 163 from which the resist material 101 is ejected onto the wafer 100. The ejection unit 163 is two-dimensionally driven parallel to the wafer 100. The imprint apparatus 1 controls ejection of the resist material 101 from the ejection unit 163 based on a drop recipe defining an application amount distribution of a resist material. An amount of the resist material 101 applied can be locally changed by controlling an amount of the resist material 101 ejected from the ejection unit 163.

The droplet recipe is generated based on design data on a design pattern (alternatively, a resist pattern or a template pattern may be also applied). The droplet recipe is, for example, defined so that an amount of the resist material 101 applied is increased in a portion in which the density of a resist pattern is high and an amount of the resist material 101 applied is reduced in a portion in which the density of a resist pattern is low.

The application amount distribution in the droplet recipe is, for example, defined by an amount (ejection amount) of one droplet of a resist material ejected from a nozzle and an ejection position of each droplet. In FIG. 1A, droplets of the resist material 101 are dropped to positions corresponding to recess portions of a template 102 by the imprint apparatus 1.

Next, the template 102 is pressed against the wafer 100 to which the resist material 101 is applied. Then, the resist material 101 enters the recess portions of the template pattern formed on the template 102 by capillary action. After the resist material 101 sufficiently enters the template pattern, as shown in FIG. 1B, the template 102 is irradiated with ultraviolet rays from above. The template 102 is formed of a material, such as quartz, transparent to ultraviolet rays (UV light). The UV light emitted to the template 102 from above passes through the template 102 to be emitted to the resist material 101. The resist material 101 is cured by UV light irradiation.

After the resist material 101 is cured, the template 102 is released. As shown in FIG. 1C, a resist pattern by the cured resist material 101 is formed on the wafer 100.

Next, the imprint apparatus 1 is explained in detail. The imprint apparatus 1 includes an imprint unit 2 and an imprint control unit 3. The imprint control unit 3 performs control of the imprint unit 2.

In the imprint unit 2, a wafer chuck 165, a wafer stage 166, the template 102, a template holding mechanism 169, the ejection unit 163, a pressurizing device 164, a UV light source 167, and the like are arranged in the same chamber 162. Moreover, the chamber 162 is supported by a stage surface plate 168 and a vibration removal board 170. The wafer chuck 165 holds the wafer 100. The wafer stage 166 is a movable stage on which the wafer chuck 165 is placed.

The wafer 100 is placed on the wafer chuck 165 in the chamber 162. The template holding mechanism 169 holds the template 102. Sealed space is provided between the template holding mechanism 169 and the template 102. The center portion of the template 102 can be expanded by pressurizing the space by the pressurizing device 164. When pressing the template 102 against the wafer 100, the space is pressurized.

The wafer stage 166 moves the wafer 100 under the ejection unit 163. The ejection unit 163 applies a resist material to the wafer 100 by an ink jet method. The imprint mechanism of the imprint unit 2 is a step and repeat system. In other words, the wafer 100 is moved after performing imprinting for one shot.

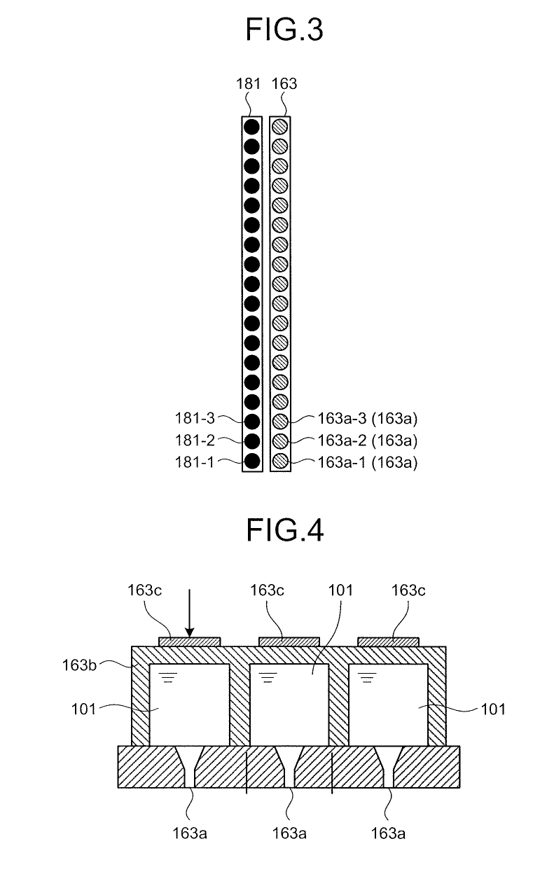

FIG. 3 is a diagram illustrating the schematic configuration of the ejection unit 163 viewed from a side of ejection ports 163a. FIG. 4 is a partially enlarged cross-sectional view illustrating a detailed configuration of the ejection unit 163. In the ejection unit 163, a plurality of the ejection ports 163a that eject the resist material 101 as droplets is aligned. The ejection unit 163 can eject a plurality of droplets at a time by including a plurality of the ejection ports 163a.

As shown in FIG. 4, an ink tank 163b is provided to correspond to each ejection port 163a. A piezo element 163c is provided outside the ink tank 163b. The volume of the ink tank 163b is compressed by applying voltage to the piezo element 163c, so that the resist material 101 is ejected from the ejection port 163a as a droplet. The ejection unit 163 applies the resist material 101 to the wafer 100 by ejecting the resist material 101 while moving in a direction approximately vertical to the alignment direction of the ejection ports 163a.

As shown in FIG. 3, a CCD line sensor (determining unit) 181 is provided near the ejection unit 163. The CCD line sensor 181 detects the end portion of the wafer 100 to determine whether the wafer 100 is present in an ejection destination of the resist material 101 from the ejection unit 163. The CCD line sensor 181 transmits a determination result to a prohibition command generating unit to be described later.

The CCD line sensor 181 can detect the presence or absence of the wafer 100 at a position to be an ejection destination of the resist material 101 at a plurality of detection points. In the CCD line sensor 181, the detection points are provided to be parallel to the alignment direction of the ejection ports 163a. The ejection ports 163a and the detection points of the CCD line sensor 181 are approximately in one-to-one correspondence with each other. In other words, the presence or absence of the wafer 100 at a position to be an ejection destination of the resist material 101 can be determined by the CCD line sensor 181 for each ejection port 163a. More specifically, the presence or absence of the wafer 100 in an ejection destination of the resist material 101 from an ejection port 163a-1 is determined by a detection point 181-1, the presence or absence of the wafer 100 in an ejection destination of the resist material 101 from an ejection port 163a-2 is determined by a detection point 181-2, and the presence or absence of the wafer 100 in an ejection destination of the resist material 101 from an ejection port 163a-3 is determined by a detection point 181-3.

The CCD line sensor 181 is explained as an example of the determining unit, however, it is not limited to this, and other sensors may be used as long as the presence or absence of a wafer can be detected. For example, a photosensor may be used.

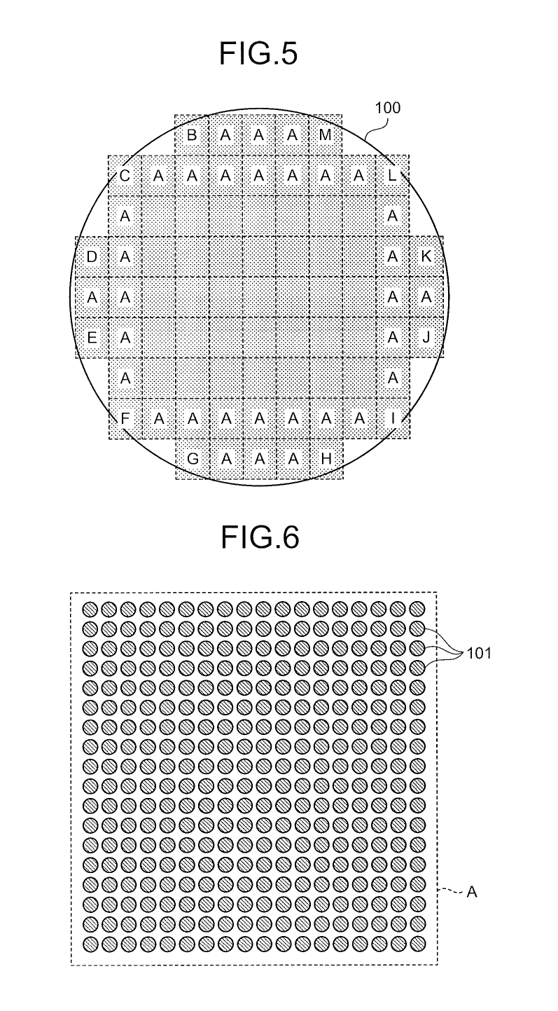

FIG. 5 is a plan view of the wafer 100 for explaining an arrangement of imprint positions. Each rectangle shown in FIG. 5 is an area (hereinafter, one shot area) in which a resist pattern is formed by one imprinting. FIG. 6 is a diagram illustrating an application example of a resist material by a drop recipe.

As shown in FIG. 5, a resist pattern is formed substantially on the whole surface of the wafer 100 by performing imprinting a plurality of times while shifting the imprint position. As shown in FIG. 6, the resist material 101 is applied to each imprint position. The wafer 100 is present in the whole area in the imprint position A. Therefore, as shown in FIG. 6, no particular problem occurs even if the resist material 101 is applied to the whole area of the imprint position A.

On the other hand, in imprint positions B to M, part thereof protrudes from the end portion of the wafer 100, so that an area, in which the wafer 100 is not present in an ejection destination of the resist material 101, occurs. An area, which partially protrudes from the end portion of the wafer 100 as the imprint positions B to M, is called also as a chipped shot area in the explanation below.

If the resist material 101 is applied to the whole area of a chipped shot area, the resist material 101 ejected toward an area protruding from the end portion of the wafer 100 adheres to the wafer stage 166 and the like, which may cause generation of dust and failure of the imprint apparatus 1.

Thus, the imprint apparatus 1 according to the present embodiment performs control of prohibiting ejection of a resist material toward an area protruding from the end portion of the wafer 100. The control of prohibiting ejection of the resist material 101 is explained in detail below.

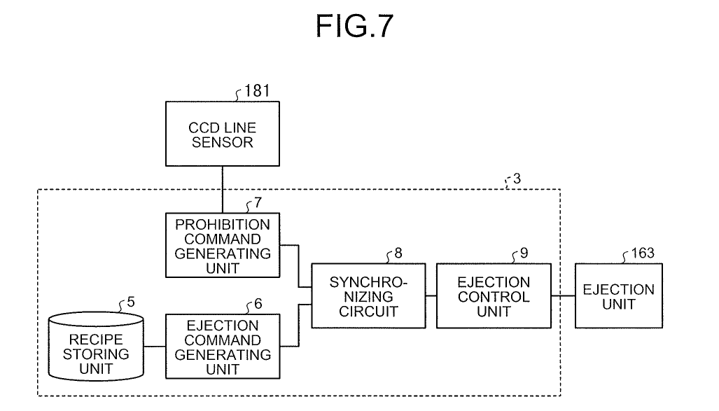

FIG. 7 is a block diagram illustrating the schematic configuration of the imprint control unit 3. The imprint control unit 3 includes a recipe storing unit 5, an ejection command generating unit 6, a prohibition command generating unit 7, a synchronizing circuit 8, and an ejection control unit 9.

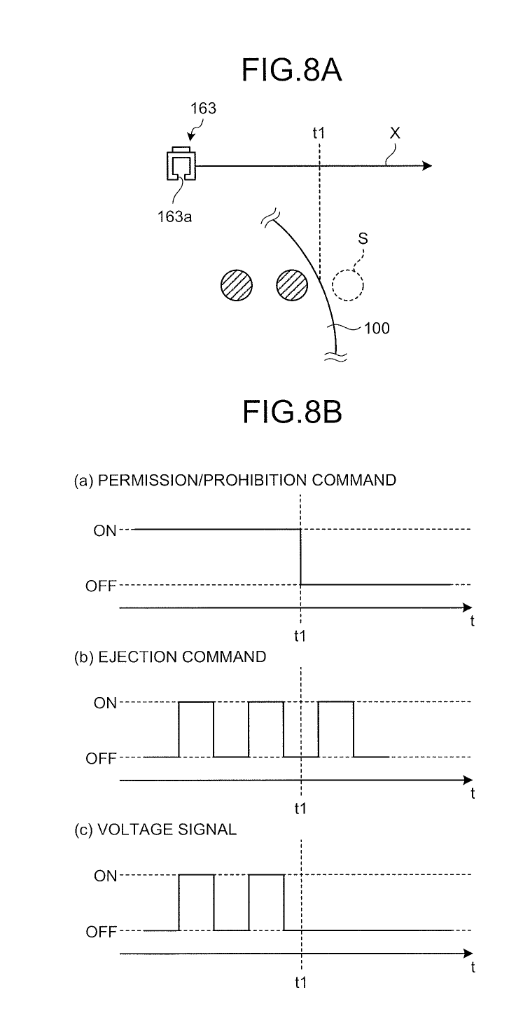

FIG. 8A is a diagram illustrating an application example of the resist material 101 at the end portion of the wafer 100. FIG. 8B is a timing chart for explaining each command when applying the resist material 101 to the end portion of the wafer 100 shown in FIG. 8A. FIG. 8A illustrates a case where a resist material is applied while the ejection unit 163 moving in a direction indicated by an arrow X and the wafer 100 disappears from an ejection destination of the resist material 101 after a time t1. Specifically, if the resist material 101 is ejected after the time t1, the resist material is applied to the outside (area S) of a wafer. In the explanation of the imprint control unit 3 below, ejection control in the application example shown in FIG. 8A is explained as an example.

The recipe storing unit 5 is a storage device, such as a ROM (Read Only Memory) and a RAM (Random Access Memory), and stores the above-described droplet recipe.

The ejection command generating unit 6 generates an ejection command for causing the ejection unit 163 to eject the resist material 101 based on the droplet recipe stored in the recipe storing unit 5. The ejection command is information indicating an ejection amount and an ejection timing of the resist material 101, and the like. In the present embodiment, because the resist material 101 is ejected from the ejection port 163a by applying voltage to the piezo element 163c (see also FIG. 3) included in the ejection unit 163, so that, as shown in FIG. 8B(b), the ejection command is generated as an on/off signal of voltage. The ejection command generating unit 6 generates an ejection signal simply based on the droplet recipe regardless of to which imprint position among the imprint positions A to M the resist material 101 is applied. In other words, the droplet recipes according to the positions of the imprint positions A to M are not prepared in the recipe storing unit 5 and the recipe storing unit 5 basically stores only the droplet recipe with which the resist material 101 can be appropriately applied to the imprint position A. Moreover, the ejection command generating unit 6 transmits the generated ejection command to the synchronizing circuit 8.

The prohibition command generating unit 7 generates a prohibition command for prohibiting ejection of the resist material 101 from the ejection unit 163 and a permission command for permitting ejection based on the determination result of the presence or absence of the wafer 100 transmitted from the CCD line sensor 181 (in the following explanation, the prohibition command and the permission command are collectively called a permission/prohibition command in some cases). More specifically, while it is determined that the wafer 100 is not present in an ejection destination of the resist material 101 from the ejection port 163a, the prohibition command generating unit 7 generates an off signal for forcibly turning off application of voltage to the piezo element 163c corresponding to the ejection port 163a as the prohibition command. When applying the resist material 101 to the imprint positions B to M, a state occurs in which the wafer 100 is not present in an ejection destination.

Moreover, while it is determined that the wafer 100 is present in an ejection destination of the resist material 101, the prohibition command generating unit 7 generates also a permission signal for permitting ejection of the resist material 101 from the ejection unit 163. More specifically, the prohibition command generating unit 7 generates an on signal for turning on application of voltage to the piezo element 163c as the permission command.

FIG. 8B(a) is a timing chart illustrating a command generated in the prohibition command generating unit 7. FIG. 8A(a) illustrates that the permission command is generated up to the time t1 and the prohibition command is generated after the time t1. The prohibition command generating unit 7 transmits the generated permission/prohibition command to the synchronizing circuit 8.

The synchronizing circuit 8 synchronizes the ejection command transmitted from the ejection command generating unit 6 with the permission/prohibition command transmitted from the prohibition command generating unit 7 and transmits them to the ejection control unit 9.

The ejection control unit 9 generates a voltage application signal for applying voltage to the ejection unit 163 based on the ejection command and the permission/prohibition command transmitted from the synchronizing circuit 8 and applies voltage to the piezo element 163c according to the generated voltage signal. The ejection control unit 9 generates the voltage signal by combining the ejection command and the permission/prohibition command.

FIG. 8B(c) illustrates the voltage signal generated by combining the ejection command shown in FIG. 8B(b) and the permission/prohibition command shown in FIG. 8B(a). The ejection control unit 9 generates the voltage signal by giving priority to the ejection command while the permission command is generated (up to the time t1) and giving priority to the prohibition command while the prohibition command is generated (after the time t1).

With the voltage signal generated as above, as shown in FIG. 8B(c), voltage is applied to the piezo element 163c by the voltage signal according to the ejection command up to the time t1 in which the wafer 100 is present in an ejection destination. That is, application of the resist material 101 according to the droplet recipe is performed up to the time t1. Then, priority is given to the prohibition command after the time t1 at which the wafer 100 disappears from an ejection destination, so that the voltage signal is turned off and therefore the resist material 101 is not applied to the outside of the wafer 100.

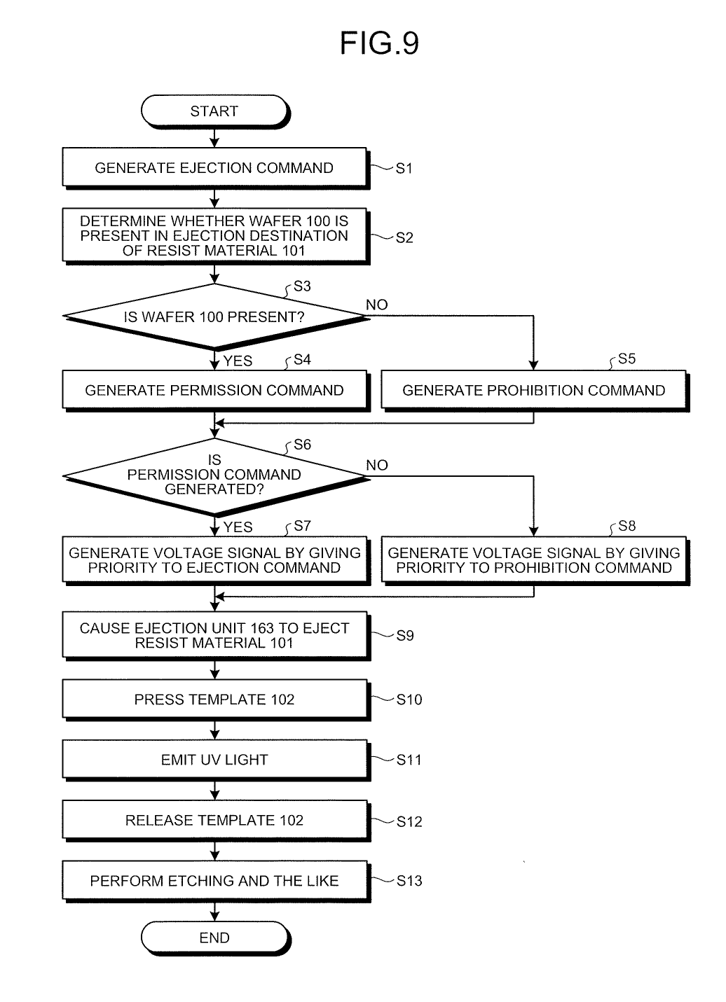

FIG. 9 is a flowchart for explaining a manufacturing method of a semiconductor substrate by the imprint apparatus 1 described above. First, the ejection command is generated based on the droplet recipe (Step S1). Next, it is determined whether the wafer 100 is present in an ejection destination of the resist material 101 (Step S2), and when the wafer 100 is present (Yes at Step S3), the permission command is generated (Step S4). When the wafer 100 is not present (No at Step S3), the prohibition command is generated (Step S5).

Then, when the permission command is generated (Yes at Step S6), the voltage signal is generated by giving priority to the ejection command (Step S7) and, when the prohibition command is generated (No at Step S6), the voltage signal is generated by giving priority to the prohibition command (Step S8), thereby causing the ejection unit 163 to eject the resist material 101 (Step S9).

Then, the template 102 is pressed against the resist material 101 applied to the wafer 100 (Step S10) and the resist material 101 is caused to cure by being irradiated with UV light (Step S11). Thereafter, the template 102 is released (Step S12), and processing, such as etching with the cured resist material 101 as a mask, is performed (Step S13), thereby manufacturing a semiconductor substrate.

As explained above, ejection of the resist material 101 is controlled based on the voltage signal combined by giving priority to the prohibition command, so that the resist material 101 can be prevented from being applied to the outside of the end portion of the wafer 100. Consequently, generation of dust and failure of the imprint apparatus 1 due to the resist material 101 protruding from the wafer 100 can be suppressed.

In order to suppress the resist material 101 from protruding from the wafer 100, for example, a method of avoiding application of the resist material 101 to the imprint positions B to M is also considered. However, the number of semiconductor chips obtained from one wafer 100 decreases by reducing the application area of the resist material 101. Moreover, the surface of the wafer 100 is polished in the subsequent process in some cases. For example, after etching at Step S13, an oxide film is formed on the surface of the wafer 100 from which a resist material is removed. On the surface of the oxide film, recesses and projections are formed due to the effect of recesses and projections formed on the surface of the wafer 100 by the etching. Therefore, the surface of the oxide film is made smooth in some cases by polishing (CMP (Chemical Mechanical Polishing)) the surface of the oxide film. In this case, when the resist material 101 is not applied to the imprint positions B to M, etching is performed in the imprint positions B to M differently from the imprint position A, so that a difference occurs in the recesses and projections on the surface. Consequently, the recesses and projections of the oxide film formed in the peripheral area of the wafer 100 including the imprint positions B to M become different from the recesses and projections of the oxide film formed in the central area of the wafer 100. In this case, an area, in which the oxide film comes into contact with a polishing surface plate (not shown), becomes different between the case of polishing the peripheral area of the wafer 100 and the case of polishing the central area of the wafer 100, thereby causing a difference in the polishing rate and the like. Therefore, the processing accuracy of the wafer 100 (oxide film) may be affected.

On the other hand, in the present embodiment, because the resist material 101 can be applied to the imprint positions B to M while suppressing the resist material 101 from protruding from the wafer 100, the application area of the resist material 101 can be made close to the end portion of the wafer 100. Consequently, the effect of the difference in the polishing position on the processing accuracy can be suppressed.

Moreover, because application of the resist material 101 using the droplet recipe can be performed also to the imprint positions B to M, it is possible to make the application density of the resist material 101 in the imprint position A and the application density of the resist material 101 in the imprint positions B to M approximately equal. Therefore, the effect of the difference in the polishing position on the processing accuracy can be further suppressed.

Moreover, because it is determined whether to actually eject the resist material 101 by determining whether the wafer 100 is present or absent in an ejection destination of the resist material 101 in situ by the CCD line sensor 181 while moving the ejection unit 163, application of the resist material 101 with suppressed protrusion thereof can be performed without additionally providing a unit of detecting the position of the wafer 100. Consequently, the cost can be suppressed.

Moreover, if the application area of the resist material 101 is made as close as possible to the end portion of the wafer 100, as shown in FIG. 5, many chipped shot areas, such as the imprint positions B to M, occur. In the present embodiment, even when ejection of the resist material 101 is instructed by the ejection command, if it is determined that the wafer 100 is not present in an ejection destination, ejection of the resist material 101 is forcibly prohibited by the prohibition command. Therefore, the resist material 101 can be applied to the imprint positions B to M by using the droplet recipe corresponding to an area, such as the imprint position A, which does not becomes a chipped shot, without any change. Therefore, droplet recipes corresponding to the imprint positions B to M do not need to be stored in the recipe storing unit 5. Therefore, the number of droplet recipes stored in the recipe storing unit 5 can be suppressed.

Typically, a droplet recipe tends to have a large data capacity, so that a large-capacity storage device is needed for storing many droplet recipes, leading to cost increase. On the other hand, in the present embodiment, because the number of droplet recipes to be stored in the recipe storing unit 5 can be suppressed, the required capacity for the recipe storing unit 5 can be suppressed and therefore cost increase can be suppressed.

Moreover, many corrections are made to a droplet recipe in a process of optimizing the application amount distribution of the resist material 101. If droplet recipes corresponding to the imprint positions B to M are also corrected in every correction, labor and cost increase for those corrections. On the other hand, in the present embodiment, because it is sufficient to correct only the droplet recipe corresponding to the imprint position A, labor for correction of the droplet recipe can be saved, enabling to suppress cost increase.

Furthermore, the ejection ports 163a provided in the ejection unit 163 and the detection points of the CCD line sensor 181 are in one-to-one correspondence with each other, a detection signal by each detection point of the CCD line sensor 181 can be used directly as the permission command or the prohibition command to the ejection port 163a corresponding to the detection point, so that control can be simplified.

In the present embodiment, the CCD line sensor 181 is provided only on one side of the ejection unit 163 as shown in FIG. 4, however, the CCD line sensor 181 may be provided on both sides of the ejection unit 163. In this case, the ejection ports 163a and the detection positions of the CCD line sensor 181 are configured to have one-to-one correspondence with each other by switching the CCD line sensor 181 to be used according to the traveling direction of the ejection unit 163.

Moreover, the CCD line sensor 181 may be configured to determine the presence or absence of the wafer 100 at a position advanced from an ejection destination, to which the resist material 101 is actually ejected from the ejection unit 163, in the traveling direction of the ejection unit 163. In this case, it is possible to cause the resist material 101 not to be applied to a fixed area from the end portion of the wafer 100, for example, by delaying an ejection signal by the synchronizing circuit 8. In this case, it is preferable to arrange the CCD line sensor 181 on both sides of the ejection unit 163 so that the CCD line sensor 181 to be used can be switched according to the traveling direction of the ejection unit 163.

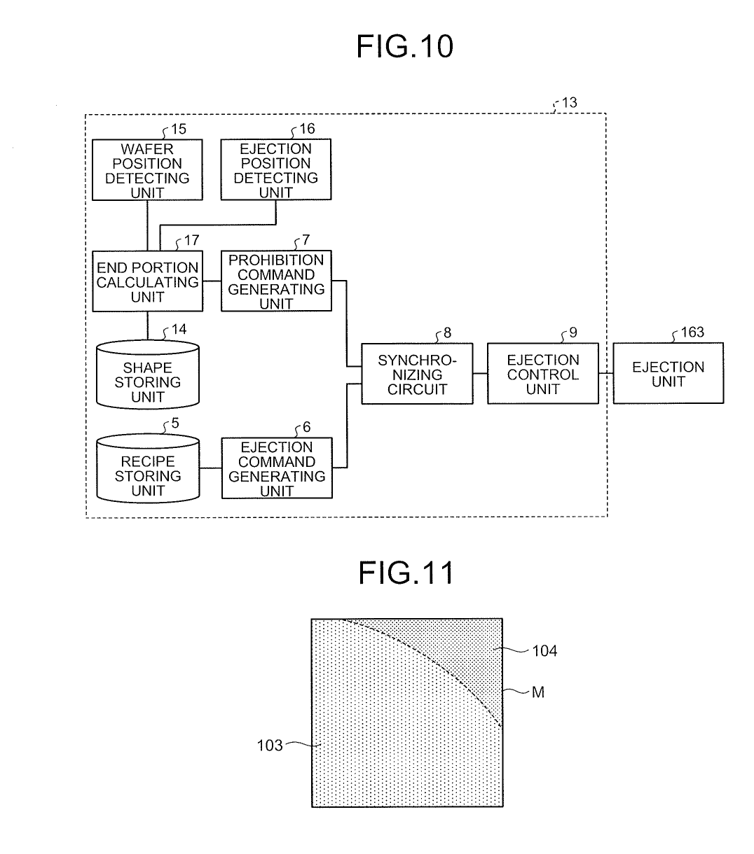

FIG. 10 is a block diagram illustrating a schematic configuration of an imprint control unit 13 included in an imprint apparatus in the second embodiment. Configurations same as those in the above embodiment are given the same reference numerals and detailed explanation thereof is omitted. In the present embodiment, the imprint control unit 13 includes a shape storing unit 14, a wafer position detecting unit (substrate position detecting unit) 15, an ejection position detecting unit 16, and an end portion calculating unit 17.

The shape storing unit 14 stores shape information indicating the shape of the wafer 100. The wafer position detecting unit 15 detects the position of the wafer 100 by detecting the position of the wafer stage 166 in the imprint unit 2 (see also FIG. 2). The ejection position detecting unit 16 detects the position of the ejection unit 163 in the imprint unit 2. The wafer position detecting unit 15 and the ejection position detecting unit 16 are, for example, potentiometers.

The end portion calculating unit 17 calculates the position of the end portion of the wafer 100 based on the detection result of the position of the wafer 100 by the wafer position detecting unit 15 and the shape information stored in the shape storing unit 14. Typically, during application of the resist material 101 to one shot area, the wafer 100 is stopped. Moreover, the shape of the wafer 100 does not change during application of the resist material 101. Therefore, the position of the end portion of the wafer 100 is calculated relatively easily.

Then, the end portion calculating unit 17 determines whether the wafer 100 is present in an ejection destination of the resist material 101 from the ejection unit 163 based on the detection result of the position of the ejection unit 163 by the ejection position detecting unit 16 and the calculated position of the end portion of the wafer 100. Then, the end portion calculating unit 17 transmits the determination result to the prohibition command generating unit 7. Generation of the prohibition command based on the determination result and the like are similar to the above embodiment, so that detailed explanation thereof is omitted.

In this manner, the position of the end portion of the wafer 100 is calculated based on the position and the shape of the wafer 100 and it is determined whether the wafer 100 is present in an ejection destination of the resist material 101, so that the resist material 101 can be prevented from being applied to the outside of the end portion of the wafer 100. Consequently, generation of dust and failure of the imprint apparatus 1 due to the protruded resist material 101 can be suppressed.

Next, an imprint apparatus according to the third embodiment is explained. The imprint apparatus according to the third embodiment includes the imprint control unit 13 having a configuration approximately similar to that shown in FIG. 10. In the third embodiment, the shape information indicating the shape of the wafer 100 is stored in the shape storing unit 14 in the similar manner to the second embodiment. The end portion calculating unit 17 calculates the position of the end portion of the wafer 100 in advance based on the shape information on the wafer 100. Then, the prohibition command generating unit 7 determines whether a wafer is present in an ejection destination of the resist material 101 based on the calculated position of the end portion, generates in advance prohibited area partition information indicating the position of the ejection unit 163 for which the prohibition command is to be generated, and stores it, for example, in the recipe storing unit 5. The prohibited area partition information can be generated in advance corresponding to the whole area of an imprint position or the whole area of the wafer 100.

FIG. 11 is a diagram illustrating an example of the prohibited area partition information for one shot. FIG. 11 exemplifies the prohibited area partition information corresponding to the imprint position M. As shown in FIG. 11, an area inwardly from the end portion of the wafer 100 is a permitted area 103 for which the permission command is generated and an area outwardly from the end portion of the wafer 100 is a prohibited area 104 for which the prohibition command is generated.

The prohibition command generating unit 7 determines whether an ejection destination of the resist material 101 from the ejection unit 163 is the permitted area 103 or the prohibited area 104 based on the detection result by the ejection position detecting unit 16 and the prohibited area partition information and generates the permission/prohibition command.

As explained above, in the third embodiment, application of the resist material 101 with suppressed protrusion thereof from the wafer 100 can be performed by generating the prohibited area partition information in advance. Consequently, a droplet recipe does not need to be prepared for each chipped shot area, so that cost can be suppressed.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the sprit of the inventions. The accompanying claims and their equivalents are intended to cover such forms or modifications as would fall within the scope and spirit of the inventions.

What is claimed is:

1. An imprint apparatus that applies a curable resin material to a processing target substrate and transfers a pattern of a semiconductor integrated circuit formed on a template onto the curable resin material applied to the processing target substrate, the apparatus comprising:
an ejection unit that ejects the curable resin material toward the processing target substrate;
a recipe storing unit that stores therein a drop recipe indicating an application amount distribution of the curable resin material to the processing target substrate;
an ejection command generating unit that generates an ejection command of the curable resin material to the ejection unit based on the drop recipe;
a determining unit that determines whether the processing target substrate is present in an ejection destination of the curable resin material from the ejection unit;
a prohibition command generating unit that, when the determining unit determines that the processing target substrate is not present, generates an ejection prohibition command of the curable resin material to the ejection unit; and
an ejection control unit that causes the ejection unit to eject the curable resin material by giving priority to the ejection prohibition command over the ejection command.

2. The imprint apparatus according to claim 1, wherein the ejection unit is configured by aligning a plurality of ejection ports.

3. The imprint apparatus according to claim 2, wherein the determining unit is a CCD line sensor arranged parallel to an alignment direction of the ejection ports.

4. The imprint apparatus according to claim 3, wherein detection positions by the CCD line sensor and positions to be an ejection destination of the curable resin material by the ejection ports are approximately in one-to-one correspondence with each other.

5. The imprint apparatus according to claim 1, further comprising:
a substrate position detecting unit that detects a position of the processing target substrate;
a ejection position detecting unit that detects a position of the ejection unit; and
a shape storing unit that stores therein a shape of the processing target substrate.

6. The imprint apparatus according to claim 5, wherein the determining unit determines whether the processing target substrate is present in an ejection destination of the curable resin material from a position of the processing target substrate, a position of the ejection unit, and a shape of the processing target substrate.

7. The imprint apparatus according to claim 5, wherein
the determining unit determines an area, in which the processing target substrate is not present, in advance from a shape of the processing target substrate, and
the prohibition command generating unit determines an ejection destination of the curable resin material based on a position of the processing target substrate and a position of the ejection unit and, when determined ejection destination is an area, which is determined that the processing target substrate is not present, generates the ejection prohibition command.

8. The imprint apparatus according to claim 4, wherein
the ejection unit is movable over the processing target substrate,
the CCD line sensor determines whether the processing target substrate is present in an ejection destination of the curable resin material at a position advanced from a current position of ejection unit in a traveling direction, and
the imprint apparatus further includes a delay circuit that delays the prohibition command with respect to the ejection command.

9. The imprint apparatus according to claim 8, wherein the CCD line sensor is provided on both sides of the ejection unit.

10. The imprint apparatus according to claim 1, wherein the curable resin material is a photocurable resin material cured by ultraviolet irradiation.

11. A manufacturing method of a semiconductor substrate of applying a curable resin material ejected from an ejection unit to a processing target substrate and transferring a pattern of a semiconductor integrated circuit onto the curable resin material applied to the processing target substrate, the method comprising:
generating an ejection command to the ejection unit that ejects the curable resin material based on a drop recipe indicating an application amount distribution of the curable resin material to the processing target substrate;
determining whether the processing target substrate is present in an ejection destination of the curable resin material from the ejection unit;
generating, when being determined that the processing target substrate is not present, an ejection prohibition command of the curable resin material to the ejection unit;
causing the ejection unit to eject the curable resin material by giving priority to the ejection prohibition command over the ejection command; and
transferring a pattern of a semiconductor integrated circuit formed on a template onto the curable resin material applied to the processing target substrate.

12. The manufacturing method of a semiconductor substrate according to claim 11, wherein
the ejection unit is configured by aligning a plurality of ejection ports, and
the curable resin material is ejected from the ejection ports.

13. The manufacturing method of a semiconductor substrate according to claim 12, wherein the determining whether the processing target substrate is present in an ejection destination of the curable resin material is performed by a CCD line sensor arranged parallel to an alignment direction of the ejection ports.

14. The manufacturing method of a semiconductor substrate according to claim 13, wherein detection positions by the CCD line sensor and positions to be an ejection destination of the curable resin material by the ejection ports are approximately in one-to-one correspondence with each other.

15. The manufacturing method of a semiconductor substrate according to claim 11, further comprising:
storing a shape of the processing target substrate in advance;
detecting a position of the processing target substrate; and
detecting a position of the ejection unit.

16. The manufacturing method of a semiconductor substrate according to claim 15, wherein the determining whether the processing target substrate is present in an ejection destination of the curable resin material is performed based on a position of the processing target substrate, a position of the ejection unit, and a shape of the processing target substrate.

17. The manufacturing method of a semiconductor substrate according to claim 15, wherein
an area, in which the processing target substrate is not present, is determined in advance from a shape of the processing target substrate,
an ejection destination of the curable resin material is determined based on a position of the processing target substrate and a position of the ejection unit, and
when determined ejection destination is an area, which is determined that the processing target substrate is not present, the ejection prohibition command is generated.

18. The manufacturing method of a semiconductor substrate according to claim 14, wherein
the ejection unit is movable over the processing target substrate,
the CCD line sensor determines whether the processing target substrate is present in an ejection destination of the curable resin material at a position advanced from a current position of ejection unit in a traveling direction, and
the prohibition command is delayed with respect to the ejection command.

19. The manufacturing method of a semiconductor substrate according to claim 18, wherein the CCD line sensor is provided on both sides of the ejection unit.

20. The manufacturing method according to claim 11, wherein the drop recipe is stored in a ROM.
